(19) United States
(12) Patent Application Publication
(10) Pub. No.: US 2010/0289936 A1
(43) Pub. Date: Nov. 18, 2010

(54) BUFFER CIRCUIT, IMAGE SENSOR CHIP COMPRISING THE SAME, AND IMAGE PICKUP DEVICE

(76) Inventors: Hiroshi Kimura, Hyogo (JP); Masahiro Higuchi, Hyogo (JP)

Correspondence Address: MCDERMOTT WILL & EMERY LLP, 600 13TH STREET, NW, WASHINGTON, DC, 20005-3096, US

(21) Appl. No.: 12/809,921

(22) PCT Filed: Jan. 30, 2009
(86) PCT No.: PCT/JP2009/000363

§ 371 Date: Jun. 21, 2010

(30) Foreign Application Priority Data
Jan. 31, 2008 (JP) 2008-021483

(51) Int. Cl. H04N 5/335; H03L 5/00

(52) U.S. Cl. 348/308; 327/108; 348/E05.091

(57) ABSTRACT

A buffer circuit includes: first and second cascode constant current sources (11,12); a constant current source (13); a resistive load (20), where one end of the resistive load (20) is connected to an output of the first cascode constant current source (11), and the other end of the resistive load (20) is connected to an output of the constant current source (13); a first transistor (21) having a source connected to an output of the second cascode constant current source (12); a second transistor (22) having a source connected to a predetermined power supply node, a drain connected to a drain of the first transistor (21), and a gate connected to a connection point between the first cascode constant current source (11) and the resistive load (20); and a third transistor (23) having a source connected to the drain of the first transistor (21), a drain connected to a connection point between the constant current source (13) and the resistive load (20), and a gate connected to the source of the first transistor (21).

### TECHNICAL FIELD

The present invention relates to buffer circuits, and specifically to source-follower buffer circuits.

### BACKGROUND ART

Conventionally, in CMOS processes, source followers are often used as buffer circuits configured to drive a large load at high speed. A general source follower includes a constant current source, and a driving transistor connected in series to the constant current source, where the gate voltage and the source voltage of the driving transistor are an input signal and an output signal, respectively. In a saturation region, the drain current of the driving transistor is ideally constant regardless of its drain-source voltage, but in practice, the drain current increases as the drain-source voltage increases due to channel length modulation effects. This means that even if the driving transistor is biased with a constant current, the gate-source voltage changes as the drain-source voltage changes. Therefore, in the source follower in which the drain-source voltage of the driving transistor changes along with the input signal, the gate-source voltage of the driving transistor changes according to the input signal, thereby causing a gain error and distortion. In particular, when the channel length of the driving transistor is shortened in order to increase the drivability of the source follower, the gain error and the distortion are further increased. Thus, the source follower has difficulties in driving a large load with a low gain error and low distortion.

To overcome the above difficulties, it has been known that the general source follower is additionally provided with: a transistor having a source and a gate respectively connected to the drain and the source of the driving transistor, and a drain connected to a predetermined voltage node; and a constant current source connected to the drain of the driving transistor (see, for example, Patent Document 1). In this improved source follower, even if the input signal changes, the gate-source voltage of the driving transistor is kept substantially constant, so that it is possible to reduce the gain error and the distortion.

### CITATION LIST

### Patent Document

PATENT DOCUMENT 1: Japanese Patent Publication No. S60-136405 (pp. 6-7, FIG. 4)

### SUMMARY OF THE INVENTION

### Technical Problem

However, the drain-source voltage of the constant current source changes according to the input signal, thereby changing its current value, which causes the gain error and the distortion. Therefore, in order to increase the precision of the source follower, it is necessary to use a constant current source having high constancy. Such a constant current source is, for example, a cascode constant current source. As the constant current source in the improved source follower, such a cascode constant current source is used, so that it is possible to configure a high-precision source follower. However, since the cascode constant current source includes a plurality of cascode-connected transistors, using the cascode constant current source in the improved source follower may pose a new problem that the number of stages of series connection of transistors increases, thereby limiting the input range of the gate voltage of the driving transistor.

Moreover, when the general source follower drives a resistive external load, a current flowing through the driving transistor changes due to a current flowing through the external load, so that it is no longer possible to bias the driving transistor with a constant current, and thus the gain error and the distortion are caused after all. This problem arises also in the above improved source follower.

In view of the above problems, it is an objective of the present invention to provide a buffer circuit which is capable of driving a large load with high precision and allows a wide range input. It is another objective of the present invention to provide a buffer circuit capable of driving a resistive load with high precision. It is still another objective of the present invention to provide an image sensor chip including such buffer circuits and an image pickup device.

### Solution to the Problem

To solve the above problems, the present invention has the following configuration. That is, an example buffer circuit of the present invention includes: first and second cascode constant current sources; a constant current source; a resistive load, where one end of the resistive load is connected to an output of the first cascode constant current source, and the other end of the resistive load is connected to an output of the constant current source; a first transistor having a source connected to an output of the second cascode constant current source; a second transistor having a source connected to a predetermined power supply node, a drain connected to a drain of the first transistor, and a gate connected to a connection point between the first cascode constant current source and the resistive load; and a third transistor having a source connected to the drain of the first transistor, a drain connected to a connection point between the constant current source and the resistive load, and a gate connected to the source of the first transistor. A gate voltage and a source voltage of the first transistor are respectively an input signal and an output signal of the buffer circuit.

Moreover, an example buffer circuit of the present invention includes: first and second cascode constant current sources; a first cascode current mirror circuit having an output connected to an output of the first cascode constant current source; a second cascode current mirror circuit having an output connected to an input of the first cascode current mirror circuit; a first transistor having a source connected to an output of the second cascode constant current source; a second transistor having a source connected to a predetermined power supply node, a drain connected to a drain of the first transistor, and a gate connected to a connection point between the first cascode constant current source and the first cascode current mirror circuit; and a third transistor having a source connected to the drain of the first transistor, a drain connected to an input of the second cascode current mirror circuit, and a gate connected to the source of the first transistor. A gate voltage and a source voltage of the first transistor are respectively an input signal and an output signal of the buffer circuit.

In these buffer circuits, the first and the third transistors each operate as a source follower, so that the drain-source voltage of the first transistor is equal to the gate-source voltage of the third transistor, and is kept substantially constant. Moreover, these buffer circuits are each configured to have one stage of the second transistor connected to the drain of the first transistor, and yet allow a constant current having precision as high as the precision of the cascode constant current sources to flow through the second transistor due to negative feedback control of the gate voltage of the second transistor. Thus, these buffer circuits can drive a large load with high precision while ensuring a sufficiently wide input range.

It is preferable that the buffer circuit further includes at least one of a constant current source connected in parallel to the second transistor, and a capacitor, wherein one end of the capacitor is connected to the drain of the second transistor, and the other end of the capacitor is connected to the gate of the second transistor. With this configuration, oscillation caused by the negative feedback control of the second transistor can be reduced.

Furthermore, an example buffer circuit of the present invention includes: first and second cascode constant current sources; a first transistor having a source connected to an output of the second cascode constant current source; a second transistor having a source connected to a first power supply node, a drain connected to a drain of the first transistor, and a biased gate; a third transistor having a source connected to the drain of the first transistor, a drain connected to an output of the first cascode constant current source, and a gate connected to the source of the first transistor; and a fourth transistor having a source connected to a second power supply node, a drain connected to the drain of the second transistor, and a gate connected to the drain of the third transistor. A gate voltage and a source voltage of the first transistor are respectively an input signal and an output signal of the buffer circuit. Thus, this example buffer circuit is configured more easily than the above buffer circuits, and can drive a large load with high precision while ensuring a sufficiently wide input range as in the case of the above buffer circuits.

Moreover, an example buffer circuit of the present invention includes: first and second cascode constant current sources; a first transistor having a drain connected to an output of the first cascode constant current source, and a source connected to an output of the second cascode constant current source; a second transistor having a source connected to a gate of the first transistor, and a drain connected to the output of the second cascode constant current source; and a third transistor having a source connected to a predetermined power supply node, a drain connected to the source of the second transistor, and a gate connected to the drain of the first transistor. A gate voltage and a source voltage of the second transistor are respectively an input signal and an output signal of the buffer circuit. Preferably, the buffer circuit further includes a third cascode constant current source configured to supply a constant current to the source of the second transistor.

In the buffer circuit, the first and the second transistor each operate as a source follower, so that the drain-source voltage of the second transistor is equal to the gate-source voltage of the first transistor, and is kept substantially constant. Moreover, when a resistive external load is provided, the gate voltage of the third transistor is controlled using a negative feedback so that a current flowing through the external load is compensated. Thus, the buffer circuit can drive the resistive load with high precision.

Moreover, an example image sensor chip of the present invention includes: an image sensor; and a column-parallel ADC, wherein the column-parallel ADC includes any one of the above buffer circuits, a ramp generation circuit configured to supply a ramp signal to the buffer circuit, and a plurality of comparators configured to compare signals output from respective ones of pixel rows of the image sensor with an output of the buffer circuit. Furthermore, an image pickup device includes the above image sensor chip.

### ADVANTAGES OF THE INVENTION

According to the present invention, it is possible to provide a buffer circuit which is capable of driving a large load with high precision and allows a wide range input, and a buffer circuit capable of driving a resistive load with high precision. Moreover, it is possible to improve the quality of image pickup data of an image sensor chip including such a buffer circuit, and further of an image pickup device including the image sensor chip.

### BRIEF DESCRIPTION OF THE DRAWINGS

FIG. 1 is a view illustrating a configuration of a buffer circuit according to a first embodiment.

FIG. 2 is a view illustrating a configuration of a buffer circuit according to a second embodiment.

FIG. 3 is a view illustrating a configuration of a buffer circuit according to a third embodiment.

FIG. 4 is a view illustrating a configuration of a buffer circuit according to a fourth embodiment.

FIG. 5 is an overview of an image pickup device.

FIG. 6 is a view illustrating a configuration of an image sensor chip.

### DESCRIPTION OF REFERENCE CHARACTERS

11 Cascode Constant Current Source (First Cascode Constant Current Source, Second Cascode Constant Current Source)
12 Cascode Constant Current Source (Second Cascode Constant Current Source, Third Cascode Constant Current Source)
13 Constant Current Source
14 Constant Current Source
15 Cascode Constant Current Source (First Cascode Constant Current Source)
16 Cascode Current Mirror Circuit (First Cascode Current Mirror Circuit)
17 Cascode Current Mirror Circuit (Second Cascode Current Mirror Circuit)
20 Resistive Load
21 PMOS Transistor (First Transistor, Second Transistor)
22 NMOS Transistor (Second Transistor)
23 NMOS Transistor (Third Transistor, First Transistor)
24 PMOS Transistor (Fourth Transistor, Third Transistor)
30 Capacitor
100 Image Pickup Device
101 Image Sensor Chip
102 Image Sensor
103 Column-parallel ADC
1032 Comparator
1034 Ramp generation circuit
1035 Buffer Circuit

### DESCRIPTION OF EMBODIMENTS

The best mode for practicing the present invention will be described below with reference to the drawings.

### First Embodiment

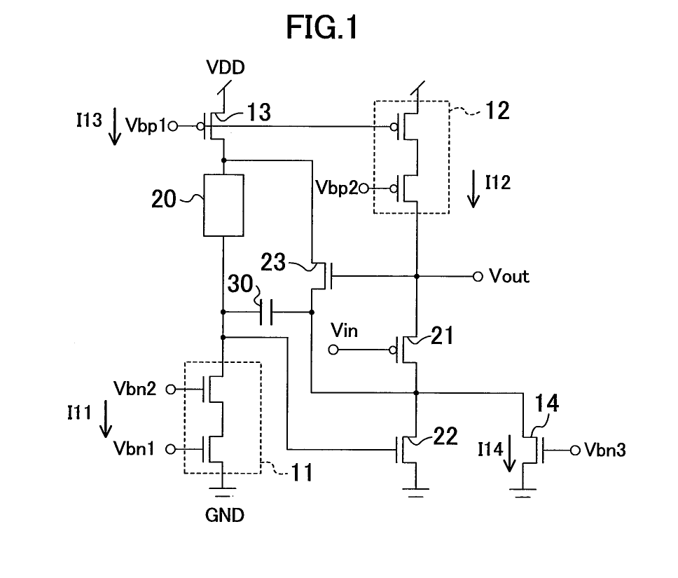

FIG. 1 illustrates a configuration of a buffer circuit according to a first embodiment. The buffer circuit can be fabricated in a CMOS process. A cascode constant current source 11 includes two cascode-connected NMOS transistors, where bias voltages Vbn1 and Vbn2 are applied to respective gates of the NMOS transistors. The cascode constant current source 11 supplies a constant current Ill. A cascode constant current source 12 includes two cascode-connected PMOS transistors, where bias voltages Vbp1 and Vbp2 are applied to respective gates of the PMOS transistors. The cascode constant current source 12 supplies a constant current I12. A constant current source 13 includes a PMOS transistor, where the bias voltage Vbp1 is applied to the gate of the PMOS transistor. The constant current source 13 supplies a constant current I13.

One end of a resistive load 20 is connected to an output of the cascode constant current source 11, and the other end of the resistive load 20 is connected to an output of the constant current source 13. The resistive load 20 can be a PMOS transistor, where a bias voltage is applied to the gate of the PMOS transistor, a resistive element, a variable resistive element, or the like.

The source of a PMOS transistor 21 is connected to an output of the cascode constant current source 12. The input signal Vin of the buffer circuit is applied to the gate of the PMOS transistor 21, and the output signal Vout of the buffer circuit is output from the source of the PMOS transistor 21. That is, the PMOS transistor 21 operates as a source follower biased with the constant current I12.

The drain of an NMOS transistor 22 is connected to the drain of the PMOS transistor 21. The source and the gate of the NMOS transistor 22 are respectively connected to a ground node and a connection point between the cascode constant current source 11 and the resistive load 20.

The gate and the source of an NMOS transistor 23 are respectively connected to the source and the drain of the PMOS transistor 21. The drain of the NMOS transistor 23 is connected to a connection point between the constant current source 13 and the resistive load 20. That is, the NMOS transistor 23 operates as a source follower biased with a constant current represented with the expression I13−I11, where the output signal Vout of the buffer circuit serves as an input of the source follower.

A constant current source 14 is connected in parallel to the NMOS transistor 22. The constant current source 14 includes an NMOS transistor, where a bias voltage Vbn3 is applied to the gate of the NMOS transistor. The constant current source 14 supplies a constant current I14. Moreover, a capacitor 30 for phase compensation is connected between the gate and the drain of the NMOS transistor 22.

In the buffer circuit according to the present embodiment, the gate voltage of the NMOS transistor 22 is controlled using a negative feedback so that a constant current represented with the expression I13−I11+I12−I14 flows through the NMOS transistor 22. Here, a voltage smaller than the source voltage (output signal Vout) of the PMOS transistor 21 by the gate-source voltage of the NMOS transistor 23 is applied to the drain of the PMOS transistor 21. Therefore, regardless of the value of the input signal Vin, the drain-source voltage of the PMOS transistor 21 is equal to the gate-source voltage of the NMOS transistor 23, and is kept substantially constant. Moreover, in the buffer circuit according to the present embodiment, the PMOS transistor 21 is biased with the constant current I12 of high precision supplied from the cascode constant current source 12. Further, as to the NMOS transistor 23 determining the drain-source voltage of the PMOS transistor 21, when the current value of the NMOS transistor 23 increases, a voltage at an output node of the cascode constant current source 13 decreases, thereby reducing the gate voltage of the NMOS transistor 22, which acts to reduce the current flowing through the NMOS transistor 23, so that the drain current of the NMOS transistor 23 is always kept constant. As a result, in the buffer circuit according to the present embodiment, it is possible to significantly reduce a gain error and distortion. Furthermore, in the buffer circuit according to the present embodiment, only one stage of transistor is provided between the drain of the PMOS transistor 21 and ground, so that the input signal Vin can be pulled down to the ground voltage. Thus, the buffer circuit according to the present embodiment can drive a large load with high precision while ensuring a sufficiently wide input range.

### Second Embodiment

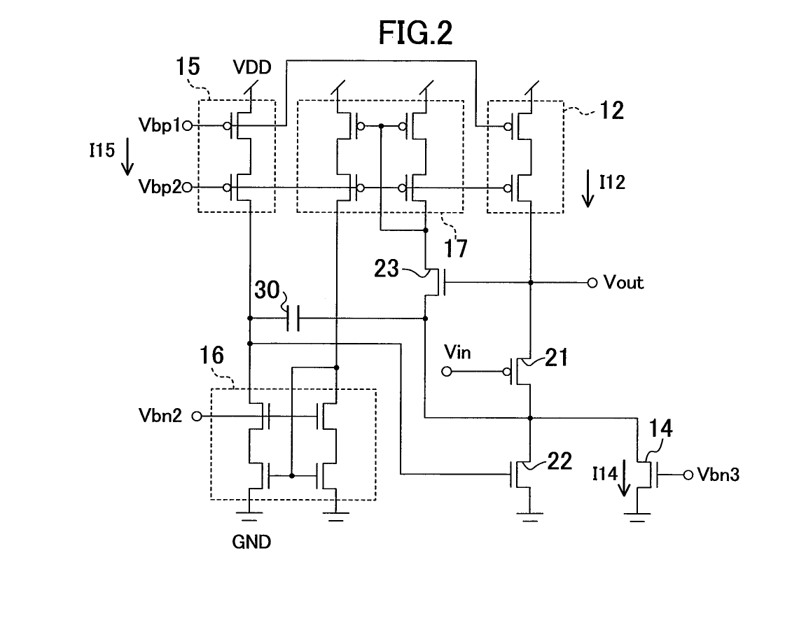

FIG. 2 illustrates a configuration of a buffer circuit according to a second embodiment. The buffer circuit can also be fabricated in a CMOS process. Cascode constant current sources 12 and 15 each include two cascode-connected PMOS transistors, where bias voltages Vbp1 and Vbp2 are applied to respective gates of the PMOS transistors. The cascode constant current source 12 supplies a constant current I12. The cascode constant current source 15 supplies a constant current I15.

A cascode current mirror circuit 16 includes two cascode-connected NMOS transistors on each of its input side and output side, where a bias voltage Vbn2 is applied to the gate of the NMOS transistor of a cascode stage on the input side and to the gate of the NMOS transistor of a cascode stage on the output side. A cascode current mirror circuit 17 includes two cascode-connected PMOS transistors on each of its input side and output side, where the bias voltage Vbp2 is applied to the gate of the PMOS transistor of a cascode stage on the input side and to the gate of the PMOS transistor of a cascode stage on the output side. An input of the cascode current mirror circuit 16 is connected to an output of the cascode current mirror circuit 17. An output of the cascode constant current source 15 is connected to an output of the cascode current mirror circuit 16.

The source of a PMOS transistor 21 is connected to an output of the cascode constant current source 12. The input signal Vin of the buffer circuit is applied to the gate of the PMOS transistor 21, and the output signal Vout of the buffer circuit is output from the source of the PMOS transistor 21. That is, the PMOS transistor 21 operates as a source follower biased with the constant current I12.

The drain of an NMOS transistor 22 is connected to the drain of the PMOS transistor 21. The source and the gate of the NMOS transistor 22 are respectively connected to a ground node and a connection point between the cascode constant current source 15 and the cascode current mirror circuit 16.

The gate and the source of an NMOS transistor 23 are respectively connected to the source and the drain of the PMOS transistor 21. The drain of the NMOS transistor 23 is connected to an input of the cascode current mirror circuit 17. In this way, the drain current of the NMOS transistor 23 is compared with the constant current I15, and a negative feedback is applied to the drain current of the NMOS transistor 23 so that the drain current of the NMOS transistor 23 equals the constant current I15. As a result, the NMOS transistor 23 operates as a source follower biased with the constant current I15, where the output signal Vout of the buffer circuit serves as an input of the source follower.

A constant current source 14 is connected in parallel to the NMOS transistor 22. The constant current source 14 includes an NMOS transistor, where a bias voltage Vbn3 is applied to the gate of the NMOS transistor. The constant current source 14 supplies a constant current I14. Moreover, a capacitor 30 for phase compensation is connected between the gate and the drain of the NMOS transistor 22.

In the buffer circuit according to the present embodiment, the gate voltage of the NMOS transistor 22 is controlled using the negative feedback so that a constant current represented with the expression I15+I12−I14 flows through the NMOS transistor 22. Therefore, as in the first embodiment, regardless of the value of the input signal Vin, the drain-source voltage of the PMOS transistor 21 is equal to the gate-source voltage of the NMOS transistor 23, and is kept substantially constant. Moreover, in the buffer circuit according to the present embodiment, the PMOS transistor 21 is biased with the constant current I12 of high precision supplied from the cascode constant current source 12, and a high-precision current equal to the constant current I15 supplied from the cascode constant current source 15 flows through the NMOS transistor 23 determining the drain-source voltage of the PMOS transistor 21, so that it is possible to significantly reduce a gain error and distortion. Furthermore, in the buffer circuit according to the present embodiment, only one stage of transistor is provided between the drain of the PMOS transistor 21 and ground, so that the input signal Vin can be pulled down to the ground voltage. Thus, the buffer circuit according to the present embodiment can drive a large load with high precision while ensuring a sufficiently wide input range.

The buffer circuit according to the present embodiment requires the cascode current mirror circuits 16 and 17, and thus has a larger circuit size than the buffer circuit of the first embodiment. In other words, the buffer circuit of the first embodiment does not use a current mirror, and thus can be configured with less number of devices than the buffer circuit according to the second embodiment, and the buffer circuit of the first embodiment has high stability.

Note that in the first and second embodiments, at least one of the constant current source 14 and the capacitor 30 may be omitted. In particular, the capacitor 30 is provided for the purpose of preventing oscillation caused by the negative feedback, but even if the capacitor 30 is not provided, providing the constant current source 14 can sufficiently suppress the oscillation. Moreover, even if both the constant current source 14 and the capacitor 30 are omitted, the oscillation can be suppressed by adjusting the characteristics of each transistor to appropriate values.

### Third Embodiment

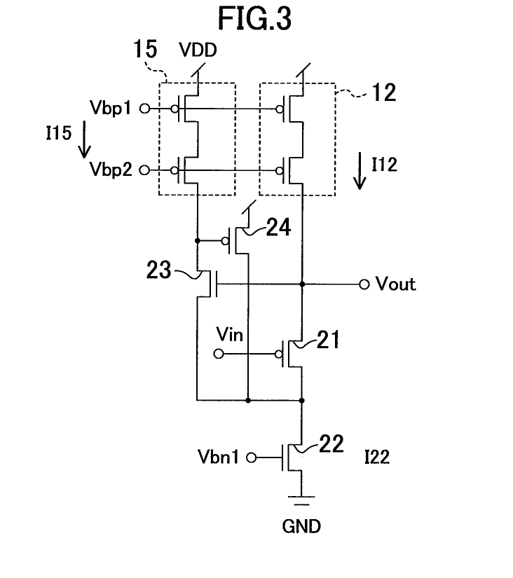

FIG. 3 illustrates a configuration of a buffer circuit according to a third embodiment. The buffer circuit can also be fabricated in a CMOS process. Cascode constant current sources 12 and 15 each include two cascode-connected PMOS transistors, where bias voltages Vbp1 and Vbp2 are applied to respective gates of the PMOS transistors. The cascode constant current source 12 supplies a constant current I12. The cascode constant current source 15 supplies a constant current I15.

The source of a PMOS transistor 21 is connected to an output of the cascode constant current source 12. The input signal Vin of the buffer circuit is applied to the gate of the PMOS transistor 21, and the output signal Vout of the buffer circuit is output from the source of the PMOS transistor 21. That is, the PMOS transistor 21 operates as a source follower biased with the constant current I12.

The drain of an NMOS transistor 22 is connected to the drain of the PMOS transistor 21. The source of the NMOS transistor 22 is connected to a ground node. A bias voltage Vbn1 is applied to the gate of the NMOS transistor 22. That is, the NMOS transistor 22 operates as a constant current source supplying a constant current I22.

The gate and the source of an NMOS transistor 23 are respectively connected to the source and the drain of the PMOS transistor 21. The drain of the NMOS transistor 23 is connected to an output of the cascode constant current source 15. That is, the NMOS transistor 23 operates as a source follower biased with the constant current I15, where the output signal Vout of the buffer circuit serves as an input of the source follower.

Moreover, the drain of a PMOS transistor 24 is connected to the drain of the NMOS transistor 22. The source and the gate of the PMOS transistor 24 are connected to a power voltage node and the drain of the NMOS transistor 23.

In the buffer circuit according to the present embodiment, the gate voltage of the PMOS transistor 24 is controlled using a negative feedback so that a constant current represented with the expression I22−I15−I12 flows through the PMOS transistor 24. Therefore, as in the first embodiment, regardless of the value of the input signal Vin, the drain-source voltage of the PMOS transistor 21 is equal to the gate-source voltage of the NMOS transistor 23, and is kept substantially constant Moreover, in the buffer circuit according to the present embodiment, the PMOS transistor 21 is biased with the constant current I12 of high precision supplied from the cascode constant current source 12, and the constant current I15 of high precision supplied from the cascode constant current source 15 flows through the NMOS transistor 23 determining the drain-source voltage of the PMOS transistor 21, so that it is possible to significantly reduce a gain error and distortion. Furthermore, in the buffer circuit according to the present embodiment, only one stage of transistor is provided between the drain of the PMOS transistor 21 and ground, so that the input signal Vin can be pulled down to the ground voltage. Thus, the buffer circuit according to the present embodiment can drive a large load with high precision while ensuring a sufficiently wide input range.

Moreover, the buffer circuit according to the present embodiment does not require a capacitor 30 for phase compensation as provided in the buffer circuits of the first and second embodiments. Therefore, the circuit area of the buffer circuit of the present embodiment can be significantly reduced in comparison to the buffer circuits of the first and second embodiments.

### Fourth Embodiment

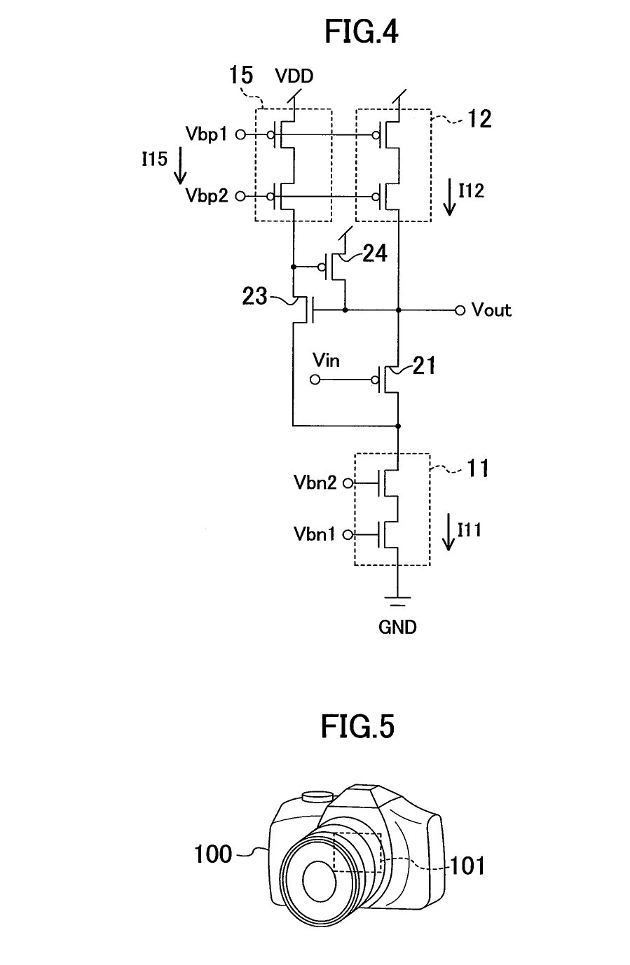

FIG. 4 illustrates a configuration of a buffer circuit according to a fourth embodiment. The buffer circuit can also be fabricated in a CMOS process. A cascode constant current source 11 includes two cascode-connected NMOS transistors, where bias voltages Vbn1 and Vbn2 are applied to respective gates of the NMOS transistors. The cascode constant current source 11 supplies a constant current I11. Cascode constant current sources 12 and 15 each include two cascode-connected PMOS transistors, where bias voltages Vbp1 and Vbp2 are applied to respective gates of the PMOS transistors. The cascode constant current source 12 supplies a constant current I12. The cascode constant current source 15 supplies a constant current I15.

The drain and the source of a PMOS transistor 21 are connected to respective outputs of the cascode constant current sources 11 and 12. The input signal Vin of the buffer circuit is applied to the gate of the PMOS transistor 21, and the output signal Vout of the buffer circuit is output from the source of the PMOS transistor 21.

The gate and the source of an NMOS transistor 23 are respectively connected to the source and the drain of the PMOS transistor 21. The drain of the NMOS transistor 23 is connected to an output of the cascode constant current source 15. That is, the NMOS transistor 23 operates as a source follower biased with the constant current I15, where the output signal Vout of the buffer circuit serves as an input of the source follower. Moreover, the PMOS transistor 21 is biased with a constant current represented with the expression I11−I15.

Moreover, the drain of a PMOS transistor 24 is connected to the source of the PMOS transistor 21. The source and the gate of the PMOS transistor 24 are connected to a power voltage node and the drain of the NMOS transistor 23.

In the buffer circuit according to the present embodiment, even if a resistive external load (not shown) is provided, the gate voltage of the PMOS transistor 24 is controlled using a negative feedback so that the current flowing through the external load is compensated. That is, when the input signal Vin is pulled up, increasing a current flowing through the external load, a current flowing through the PMOS transistor 21 decreases, and a current flowing through the NMOS transistor 23 increases. As a result, the gate voltage of the PMOS transistor 24 decreases, thereby increasing a current I24 flowing through the PMOS transistor 24 so that the equation I24=I11−I15−I12+IL (where IL is a current flowing through the external load) always holds true. Thus, as in the first embodiment, regardless of the value of the input signal Vin, the drain-source voltage of the PMOS transistor 21 is equal to the gate-source voltage of the NMOS transistor 23, and is kept substantially constant. Moreover, in the buffer circuit according to the present embodiment, the PMOS transistor 21 is biased with a difference I11−I15 between the constant currents of high precision supplied from the cascode constant current sources 11 and 15, and the constant current I15 of high precision supplied from the cascode constant current source 15 flows through the NMOS transistor 23 determining the drain-source voltage of the PMOS transistor 21, so that it is possible to significantly reduce a gain error and distortion. Thus, the buffer circuit according to the present embodiment can drive a resistive external load with high precision.

Note that the cascode constant current source 12 may be omitted. Even if the cascode constant current source 12 is omitted, the buffer circuit according to the present embodiment provides the same advantages as described above. Moreover, the same advantages as described above can also be provided by a buffer circuit having a configuration in which the polarity of all the transistors constituting the buffer circuit according to the above embodiments is reversed (that is, an NMOS transistor based source follower).

### Embodiment of Image Pickup Device and Image Sensor Chip

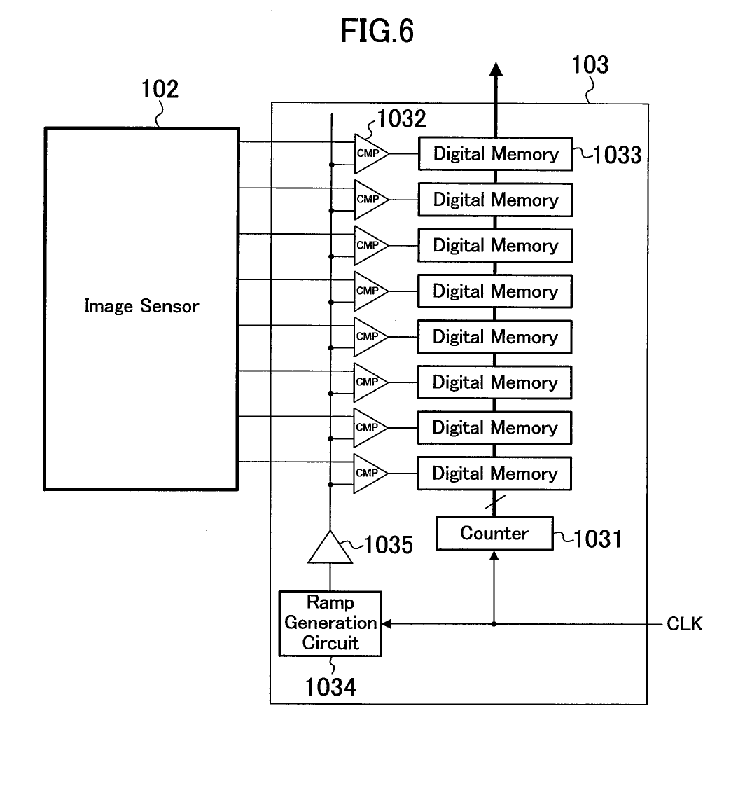

FIG. 5 illustrates an overview of an image pickup device. Specifically, an image pickup device 100 is a digital still camera, a digital video camera, or the like. The image pickup device 100 includes an image sensor chip 101. FIG. 6 illustrates a configuration of the image sensor chip 101. The image sensor chip 101 includes an image sensor 102 and a column-parallel ADC 103. The column-parallel ADC 103 includes a counter 1031, comparators 1032 and digital memories 1033 which are provided correspondingly to pixel rows of the image sensor 102, a ramp generation circuit 1034, and a buffer circuit 1035.

The ramp generation circuit 1034 generates a ramp signal in synchronization with a clock signal CLK. The counter 1031 counts pulses of the clock signal CLK, and provides a common count value to the plurality of digital memories 1033. The buffer circuit 1035 receives the ramp signal from the ramp generation circuit 1034, and supplies a common ramp signal to the plurality of comparators 1032. The comparators 1032 compare signals output from the respective pixel rows of the image sensor 102 with the output of the buffer circuit 1035. Each digital memory 1033 stores a count value of the counter 1031 at the time when an output of its corresponding comparator 1032 changes. The values stored in the plurality of digital memories 1033 are sequentially shifted and output, so that electrical signals output from the image sensor 102 can be obtained as image pickup data.

Since the image sensor 102 generally includes several thousands of pixel rows, several thousands of comparators 1032 are required. Therefore, although parasitic capacitance on an input terminal of an individual comparator 1032 is small, a collection of several thousands of comparators 1032 forms an enormously large load. Moreover, since the slope of the ramp signal is equivalent to the gain of the column-parallel ADC 103, the buffer circuit 1035 has to be able to drive a large load with high precision in order to achieve a precise A/D conversion and a variable gain. Thus, it is preferable to use the buffer circuits according to first to fourth embodiments as the buffer circuit 1035. In this way, it is possible to perform a high-precision A/D conversion of the electrical signals output from the image sensor 102, thereby allowing the quality of the image pickup data to be improved.

### INDUSTRIAL APPLICABILITY

The buffer circuit according to the present invention has a wide input range, and can drive a large load with high precision, so that is useful as, for example, a buffer circuit configured to supply a ramp signal to a column-parallel ADC which performs A/D conversion of thousands of electric signals output from an image pickup device.

1. A buffer circuit comprising:
first and second cascode constant current sources;
a constant current source;
a resistive load, where one end of the resistive load is connected to an output of the first cascode constant current source, and the other end of the resistive load is connected to an output of the constant current source;
a first transistor having a source connected to an output of the second cascode constant current source;
a second transistor having a source connected to a predetermined power supply node, a drain connected to a drain of the first transistor, and a gate connected to a connection point between the first cascode constant current source and the resistive load; and
a third transistor having a source connected to the drain of the first transistor, a drain connected to a connection point between the constant current source and the resistive load, and a gate connected to the source of the first transistor, wherein
a gate voltage and a source voltage of the first transistor are respectively an input signal and an output signal.

2. A buffer circuit comprising:
first and second cascode constant current sources;
a first cascode current mirror circuit having an output connected to an output of the first cascode constant current source;
a second cascode current mirror circuit having an output connected to an input of the first cascode current mirror circuit;
a first transistor having a source connected to an output of the second cascode constant current source;
a second transistor having a source connected to a predetermined power supply node, a drain connected to a drain of the first transistor, and a gate connected to a connection point between the first cascode constant current source and the first cascode current mirror circuit; and
a third transistor having a source connected to the drain of the first transistor, a drain connected to an input of the second cascode current mirror circuit, and a gate connected to the source of the first transistor, wherein
a gate voltage and a source voltage of the first transistor are respectively an input signal and an output signal.

3. The buffer circuit of any one of claims 1 and 2, further comprising:
a constant current source connected in parallel to the second transistor.

4. The buffer circuit of any one of claims 1, 2, and 3, further comprising:
a capacitor, wherein
one end of the capacitor is connected to the drain of the second transistor, and
the other end of the capacitor is connected to the gate of the second transistor.

5. The buffer circuit of claim 1, wherein the resistive load is a transistor whose gate is biased.

6. The buffer circuit of claim 1, wherein the resistive load is a resistive element.

7. The buffer circuit of claim 6, wherein the resistive element is a variable resistive element whose resistance value is variable.

8. A buffer circuit comprising:
first and second cascode constant current sources;
a first transistor having a source connected to an output of the second cascode constant current source;
a second transistor having a source connected to a first power supply node, a drain connected to a drain of the first transistor, and a biased gate;
a third transistor having a source connected to the drain of the first transistor, a drain connected to an output of the first cascode constant current source, and a gate connected to the source of the first transistor; and
a fourth transistor having a source connected to a second power supply node, a drain connected to the drain of the second transistor, and a gate connected to the drain of the third transistor, wherein
a gate voltage and a source voltage of the first transistor are respectively an input signal and an output signal.

9. A buffer circuit comprising:
first and second cascode constant current sources;
a first transistor having a drain connected to an output of the first cascode constant current source, and a source connected to an output of the second cascode constant current source;
a second transistor having a source connected to a gate of the first transistor, and a drain connected to the output of the second cascode constant current source; and
a third transistor having a source connected to a predetermined power supply node, a drain connected to the source of the second transistor, and a gate connected to the drain of the first transistor, wherein
a gate voltage and a source voltage of the second transistor are respectively an input signal and an output signal.

10. The buffer circuit of claim 9, further comprising:
a third cascode constant current source configured to supply a constant current to the source of the second transistor.

11. An image sensor chip comprising:
an image sensor; and
a column-parallel ADC, wherein
the column-parallel ADC includes
any one of the buffer circuits of claims 1-10,
a ramp generation circuit configured to supply a ramp signal to the buffer circuit, and
a plurality of comparators configured to compare signals output from respective ones of pixel rows of the image sensor with an output of the buffer circuit.

12. An image pickup device comprising:
the image sensor chip of claim 11.
